(19) United States
(12) Patent Application Publication
(10) Pub. No.: US 2012/0118379 A1
(43) Pub. Date: May 17, 2012

(54) DYE-SENSITIZED SOLAR CELL

(75) Inventors: Isao Inoue, Tokyo-to (JP); Naohiro Obonai, Tokyo-to (JP); Koujirou Ookawa, Tokyo-to (JP)

(73) Assignee: DAI NIPPON PRINTING CO., LTD., Tokyo-to (JP)

(21) Appl. No.: 13/386,999

(22) PCT Filed: Jul. 6, 2010
(86) PCT No.: PCT/JP2010/061487

§ 371 Date: Jan. 25, 2012

(30) Foreign Application Priority Data
Sep. 30, 2009 (JP) 2009-227758

(51) Int. Cl. H01L 31/0203

(52) U.S. Cl. 136/259

(57) ABSTRACT

Disclosed herein is a dye-sensitized solar cell that prevents reverse electron transfer by a simple method and has significantly-improved power generation efficiency. The dye-sensitized solar cell includes a base material for dye-sensitized solar cell having a base material and a first electrode layer provided on the base material; a counter electrode base material arranged so as to oppose to the base material for dye-sensitized solar cell and functions as an electrode; an electrolyte layer provided between the base material for dye-sensitized solar cell and the counter electrode base material; and a porous layer laminated on either the base material for dye-sensitized solar cell or the counter electrode base material, provided so as to come into contact with the electrolyte layer, and contains a dye-sensitizer-supported fine particle of a metal oxide semiconductor.

### TECHNICAL FIELD

The present invention relates to a dye-sensitized solar cell.

### BACKGROUND ART

In recent years, environmental issues such as global warming believed to be caused by an increase in carbon dioxide have become serious, and therefore measures against such environmental issues have been taken on a global basis. Above all, solar cells utilizing the energy of sunlight have been actively researched and developed as environmentally-friendly clean energy sources. As such solar cells, monocrystal silicon solar cells, polycrystal silicon solar cells, amorphous silicon solar cells, and compound-semiconductor solar cells have already been practically used, but these solar cells have problems such as high production cost etc. For this reason, dye-sensitized solar cells have received attention as solar cells that are environmentally friendly and can be produced at lower cost, and research and development of such dye-sensitized solar cells has been promoted.

An example of the general structure of a dye-sensitized solar cell is shown in FIGS. 7A and 7B. As shown in FIG. 7A, a general dye-sensitized solar cell 100 has a structure in which a porous layer 102 containing dye-sensitizer-supported fine particles of a metal oxide semiconductor and an electrolyte layer 101 are provided inside a sealant 103 so as to be interposed between a base material for dye-sensitized solar cell 110 having a base material 111 and a first electrode layer 112 laminated on the base material 111 and a counter electrode base material 120 functioning as an electrode. Therefore, the dye sensitizer adsorbed to the surface of the metal oxide semiconductor fine particles contained in the porous layer 102 is excited by receiving sunlight from the base material 111 side, and then excited electrons are transferred to the first electrode layer and are then transferred to the counter electrode base material through an external circuit. Then, the electrons are returned to the ground state of the dye sensitizer by a redox pair, and as a result electricity is generated. A typical example of such a dye-sensitized solar cell is a Gratzel cell whose porous layer is made of porous titanium dioxide and whose dye sensitizer content has been increased. The Gratzel cell is being subjected to extensive research as a dye-sensitized solar cell excellent in power generation efficiency. It is to be noted that, as shown in FIG. 7B, a dye-sensitized solar cell of a so-called “inverted-structure cell type” having a structure in which the porous layer 102 is provided so as to come into contact with the counter electrode base material 120 is also known.

However, such a dye-sensitized solar cell as described above has a problem of “reverse electron transfer” that is one of the factors that lower its power generation efficiency. The term “reverse electron transfer” refers to a phenomenon in which electrons flow from an electrode to an electrolyte layer. For example, in the case of the dye-sensitized solar cell shown in FIG. 7A, reverse electron transfer is a phenomenon in which electrons flow from the first electrode layer 112 to the electrolyte layer 101, and in the case of the dye-sensitized solar cell shown in FIG. 7B, reverse electron transfer is a phenomenon in which electrons flow from the counter electrode base material 120 to the electrolyte layer 101.

As methods for preventing such reverse electron transfer, for example, the following two methods are known. Each of the methods will be described below with reference to a case where it is applied to the dye-sensitized solar cell shown in FIG. 7A. One is a method in which the base material having the first electrode layer laminated thereon or the base material having the first electrode layer and the porous layer laminated thereon is immersed in a titanium tetrachloride solution or a titanium tetraisopropoxide solution to form a compact titanium oxide layer on the surface of the first electrode layer, or the surface of the first electrode layer and the surface of the porous layer to prevent the electrolyte layer from coming into contact with the first electrode layer (see, for example, Patent Literatures 1 and 2). The other is a method in which the porous layer is formed so as to cover the surface of the first electrode layer (see, for example, Patent Literature 3). However, the former has a drawback that a resin substrate having flexibility cannot be used as the base material when a titanium tetrachloride-based layer is formed because formation of such a layer requires high-temperature heat treatment. On the other hand, the latter has a critical problem that, when the electrolyte layer is a liquid, an electrolyte leaks because the porous layer is porous as its name suggests.

It has already been known that reverse electron transfer lowers the power generation efficiency of dye-sensitized solar cells, but an effective means for preventing reverse electron transfer has not yet been established.

### CITATION LIST

### Patent Literatures

Parent Literature 1: Japanese Patent Application Publication (JP-A) No. 2007-157397 (for example, paragraph [0046])
Patent Literature 2: JP-A No. 2007-073346 (for example, paragraph [0033])
Patent Literature 3: JP-A No. 2006-19072

### SUMMARY OF INVENTION

### Technical Problem

In view of the circumstances, the present inventors have extensively studied an effective means for preventing reverse electron transfer, and as a result have found the following. The findings will be described below with reference to the dye-sensitized solar cell shown in FIG. 7A. The present inventors have found that reverse electron transfer occurs in an area where the electrolyte layer and the first electrode layer come into contact with each other, and in the dye-sensitized solar cell having a general structure, the area where the electrolyte layer and the first electrode layer come into contact with each other is limited to an interface between the porous layer and the first electrode layer where the electrolyte layer comes into indirect contact with the first electrode layer with the porous layer being interposed therebetween (i.e., an interface indicated by an arrow A in FIG. 7A) and an interface between the electrolyte layer and the first electrode layer where the electrolyte layer and the first electrode layer come into direct contact with each other (i.e., an interface indicated by an arrow B in FIG. 7A). The area of the former is much larger than that of the latter, when the areas of those interfaces are compared, and therefore, the present inventors have predicted that reverse electron transfer can be efficiently prevented by reducing the area of the former. However, as a result of a further extensive study, the present inventors have found that, in spite of the fact that the area of an interface between the electrolyte layer and the first electrode layer is much smaller than that of an interface between the first electrode layer and the porous layer, reverse electron transfer that occurs at the interface between the electrolyte layer and the first electrode layer is a major factor that lowers power generation efficiency, and therefore power generation efficiency can be significantly improved by preventing reverse electron transfer at this interface.

The same goes for the inverted-structure cell-type dye-sensitized solar cell shown in FIG. 7B. That is, the present inventors have found that reverse electron transfer that occurs at an interface where the electrolyte layer and the counter electrode base material come into contact with each other is a major factor that lowers power generation efficiency, and therefore power generation efficiency can be significantly improved by preventing reverse electron transfer at this interface.

As shown in FIGS. 8A and 8B, an attempt to prevent direct contact between the first electrode layer or the counter electrode base material and the electrolyte layer has been made by providing the sealant 103 in such a manner that the ends of the porous layer 102, the ends of the electrolyte layer 101, and the surface of the first electrode layer 112 or of the counter electrode base material 120 are covered with the sealant 103. However, it has been found that reverse electron transfer cannot be completely prevented simply by providing the sealant in such a manner as described above because the electrolyte layer still penetrates into a boundary between the sealant and the porous layer and then reaches the first electrode layer or the counter electrode base material.

Under the circumstances, an object of the present invention is to provide a dye-sensitized solar cell that prevents reverse electron transfer by a simple method and has significantly-improved power generation efficiency.

### Solution to Problem

In order to achieve the above object, the present invention is directed to a dye-sensitized solar cell comprising: a base material for dye-sensitized solar cell having a base material and a first electrode layer provided on the base material; a counter electrode base material arranged so as to oppose to the base material for dye-sensitized solar cell and functions as an electrode; an electrolyte layer provided between the base material for dye-sensitized solar cell and the counter electrode base material; a porous layer laminated on the first electrode layer of the base material for dye-sensitized solar cell, provided so as to come into contact with the electrolyte layer, and contains a dye-sensitizer-supported fine particle of a metal oxide semiconductor; and a sealant provided so as to seal the electrolyte layer, wherein the electrolyte layer and the porous layer have different widths and the sealant is provided so as to cover ends of the electrolyte layer and ends of the porous layer and to prevent the electrolyte layer from coming into contact with the first electrode layer.

According to the present invention, the sealant is provided so as to cover the ends of the electrolyte layer and the ends of the porous layer and to prevent the electrolyte layer from coming into contact with the first electrode layer. This makes it possible to eliminate an area where the electrolyte layer comes into direct contact with the first electrode layer (i.e., an interface indicated by an arrow B in FIG. 7A) from the dye-sensitized solar cell according to the present invention.

Further, the electrolyte layer and the porous layer have different widths, and therefore the length of an interface between the porous layer and the sealant can be increased, which makes it possible to prevent the electrolyte layer from reaching the first electrode layer even when the electrolyte layer penetrates into a gap between the porous layer and the sealant. Therefore, according to the present invention, it is possible to prevent reverse electron transfer caused by direct contact between the electrolyte layer and the first electrode layer.

For this reason, according to the present invention, it is possible to obtain a dye-sensitized solar cell that prevents reverse electron transfer by a simple method and has significantly-improved power generation efficiency.

The present invention is also directed to a dye-sensitized solar cell comprising: a base material for dye-sensitized solar cell having a base material and a first electrode layer provided on the base material; a counter electrode base material arranged so as to oppose to the base material for dye-sensitized solar cell and functions as an electrode; an electrolyte layer provided between the base material for dye-sensitized solar cell and the counter electrode base material; a porous layer laminated on the counter electrode base material, provided so as to come into contact with the electrolyte layer, and contains a dye-sensitizer-supported fine particle of a metal oxide semiconductor; and a sealant provided so as to seal the electrolyte layer, wherein the electrolyte layer and the porous layer have different widths and the sealant is provided so as to cover ends of the electrolyte layer and ends of the porous layer and to prevent the electrolyte layer from coming into contact with a surface of the counter electrode base material.

According to the present invention, the sealant is provided so as to cover the ends of the electrolyte layer and the ends of the porous layer and to prevent the electrolyte layer from coming into contact with the counter electrode base material. This makes it possible to eliminate an area where the electrolyte layer comes into direct contact with the counter electrode base material (i.e., an interface indicated by an arrow B in FIG. 7B) from the dye-sensitized solar cell according to the present invention.

Further, the electrolyte layer and the porous layer have different widths, and therefore the length of an interface between the porous layer and the sealant can be increased, which makes it possible to prevent the electrolyte layer from reaching the counter electrode base material even when the electrolyte layer penetrates into a gap between the porous layer and the sealant. Therefore, according to the present invention, it is possible to prevent reverse electron transfer caused by direct contact between the electrolyte layer and the counter electrode base material.

For this reason, according to the present invention, it is possible to obtain a dye-sensitized solar cell that prevents reverse electron transfer by a simple method and has significantly-improved power generation efficiency.

According to the present invention, it is preferred that the electrolyte layer has a width smaller than a width of the porous layer. This is because, in this case, the dye-sensitized solar cell according to the present invention can be produced by a simple process.

Further, according to the present invention, it is also preferred that a difference in width between the electrolyte layer and the porous layer is 0.5 mm to 5 mm. This is because if the difference in width between the electrolyte layer and the porous layer is less than the above lower limit, there is a case where it is difficult to produce a dye-sensitized solar cell. In addition, there is also a possibility that, due to a reduction in the length of an interface between the porous layer and the sealant, the electrolyte layer penetrates into a gap between the porous layer and the sealant and then reaches the first electrode layer or the counter electrode base material, which makes it impossible to completely prevent reverse electron transfer. On the other hand, if the difference in width between the electrolyte layer and the porous layer exceeds the above upper limit, there is a possibility that, due to a reduction in the area of the porous layer that contributes to power generation, significant improvement in power generation efficiency cannot be expected even when reverse electron transfer can be prevented.

### Advantageous Effects of Invention

According to the present invention, it is possible to provide a dye-sensitized solar cell that prevents reverse electron transfer by a simple method and has significantly-improved power generation efficiency and excellent characteristics.

### BRIEF DESCRIPTION OF DRAWINGS

FIG. 1 is a schematic sectional view of one example of a dye-sensitized solar cell according to a first embodiment of the present invention.

FIGS. 2A and 2B are each a schematic sectional view of another example of the dye-sensitized solar cell according to the first embodiment of the present invention.

FIGS. 3A and 3B are each a schematic view for explaining a difference in width between a porous layer and an electrolyte layer provided in the dye-sensitized solar cell according to the present invention.

FIGS. 4A and 4B are each a schematic sectional view of another example of the dye-sensitized solar cell according to the first embodiment of the present invention.

FIGS. 5A to 5D are schematic views of one example of a method for producing the dye-sensitized solar cell according to the first embodiment of the present invention.

FIG. 6 is a schematic sectional view of one example of a dye-sensitized solar cell according to a second embodiment of the present invention.

FIGS. 7A and 7B are each a schematic view of a general dye-sensitized solar cell.

FIGS. 8A and 8B are each a schematic view of another general dye-sensitized solar cell.

### DESCRIPTION OF EMBODIMENTS

Hereinbelow, a dye-sensitized solar cell according to the present invention will be described in detail.

Embodiments of the dye-sensitized solar cell according to the present invention can be broadly divided into two types depending on where a porous layer is provided.

Each of the two types of embodiments of the dye-sensitized solar cell according to the present invention will be described below.

A. First Embodiment of Dye-Sensitized Solar Cell

1. Dye-Sensitized Solar Cell

A dye-sensitized solar cell according to a first embodiment of the present invention comprises: a base material for dye-sensitized solar cell having a base material and a first electrode layer provided on the base material; a counter electrode base material arranged so as to oppose to the base material for dye-sensitized solar cell and functions as an electrode; an electrolyte layer provided between the base material for dye-sensitized solar cell and the counter electrode base material; a porous layer laminated on the first electrode layer of the base material for dye-sensitized solar cell, provided so as to come into contact with the electrolyte layer, and contains a dye-sensitizer-supported fine particle of a metal oxide semiconductor; and a sealant provided so as to seal the electrolyte layer, wherein the electrolyte layer and the porous layer have different widths and the sealant is provided so as to cover ends of the electrolyte layer and ends of the porous layer and to prevent the electrolyte layer from coming into contact with the first electrode layer.

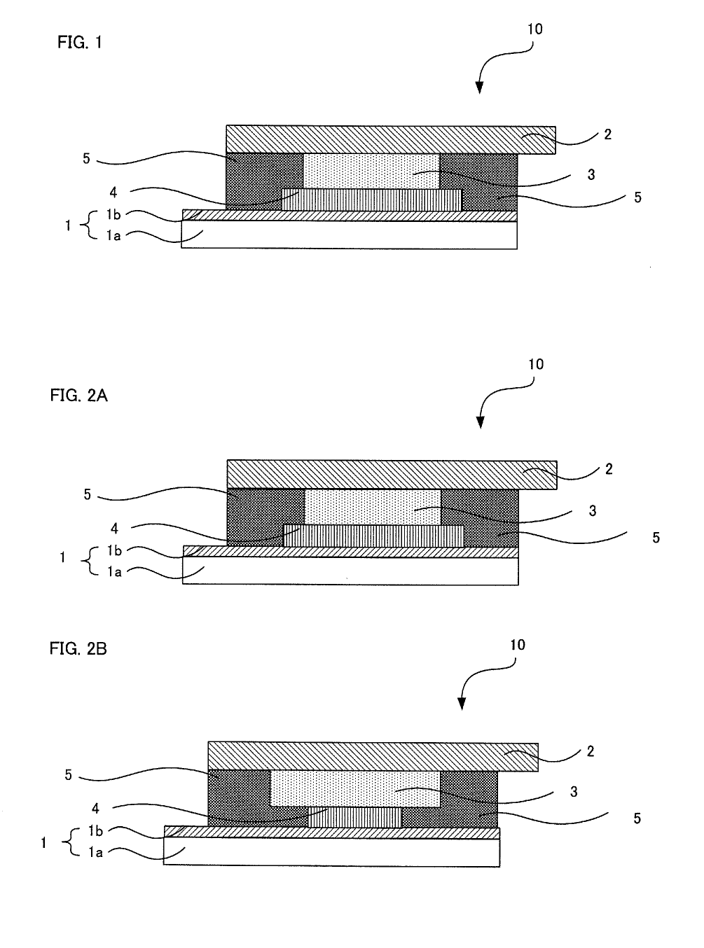

Such a dye-sensitized solar cell according to this embodiment will be described with reference to the accompanying drawings. FIG. 1 is a schematic sectional view of one example of the dye-sensitized solar cell according to this embodiment. As shown in FIG. 1, a dye-sensitized solar cell 10 according to this embodiment comprises: a base material for dye-sensitized solar cell 1 having a base material 1a and a first electrode layer 1b provided on the base material 1a; a counter electrode base material 2 arranged so as to oppose to the base material for dye-sensitized solar cell 1 and functions as an electrode; an electrolyte layer 3 provided between the base material for dye-sensitized solar cell 1 and the counter electrode base material 2; a porous layer 4 laminated on the first electrode layer 1b of the base material for dye-sensitized solar cell 1, provided so as to come into contact with the electrolyte layer 3, and contains dye-sensitizer-supported fine particles of a metal oxide semiconductor; and a sealant 5 provided so as to seal the electrolyte layer 3.

The dye-sensitized solar cell 10 as one example of this embodiment is characterized in that the electrolyte layer 3 and the porous layer 4 have different widths and the sealant 5 is provided so as to cover the ends of the electrolyte layer 3 and the ends of the porous layer 4 and to prevent the electrolyte layer 3 from coming into contact with the first electrode layer 1b.

According to this embodiment, the sealant is provided so as to cover the ends of the electrolyte layer and the ends of the porous layer and to prevent the electrolyte layer from coming into contact with the first electrode layer. This makes it possible to eliminate an area where the electrolyte layer comes into direct contact with the first electrode layer (i.e., an interface indicated by the arrow B in FIG. 7A) from the dye-sensitized solar cell according to this embodiment.

Further, the electrolyte layer and the porous layer have different widths, and therefore the length of an interface between the porous layer and the sealant can be increased. This makes it possible to prevent the electrolyte layer from reaching the first electrode layer even when the electrolyte layer penetrates into a gap between the porous layer and the sealant. Therefore, according to this embodiment, it is possible to prevent reverse electron transfer caused by direct contact between the electrolyte layer and the first electrode layer.

For this reason, according to this embodiment, it is possible to obtain a dye-sensitized solar cell that prevents reverse electron transfer by a simple method and has significantly-improved power generation efficiency.

As described above, one of the features of the dye-sensitized solar cell according to this embodiment is that the porous layer and the electrolyte layer have different widths.

The dye-sensitized solar cell according to this embodiment in which the electrolyte layer and the porous layer have different widths will be described with reference to the drawings. FIGS. 2A and 2B are each a schematic sectional view for explaining the dye-sensitized solar cell according to this embodiment in which the porous layer and the electrolyte layer have different widths. As shown in FIGS. 2A and 2B the dye-sensitized solar cell according to this embodiment in which the porous layer and the electrolyte layer have different widths may be one in which the width of the porous layer 4 is larger than that of the electrolyte layer 3 (FIG. 2A) or one in which the width of the electrolyte layer 3 is larger than that of the porous layer 4 (FIG. 2B).

Either of them is preferably used as the dye-sensitized solar cell according to this embodiment in which the porous layer and the electrolyte layer have different widths. However, one in which the width of the electrolyte layer is smaller than that of the porous layer is usually preferred. This is because, in this case, the dye-sensitized solar cell according to this embodiment can be produced by a simple process.

According to this embodiment, the difference in width between the electrolyte layer and the porous layer is not particularly limited as long as it is possible to increase the length of an interface between the porous layer and the sealant and to prevent the electrolyte layer from reaching the first electrode layer even when the electrolyte layer penetrates into a gap between the porous layer and the sealant. A specific difference in width between the electrolyte layer and the porous layer is determined based on factors such as the form or composition of the electrolyte layer, and is not uniquely determined. However, according to this embodiment, the difference in width between the electrolyte layer and the porous layer is preferably in the range of 0.5 mm to 5 mm, more preferably in the range of 1 mm to 4 mm, and even more preferably in the range of 1 mm to 2 mm. If the difference in width between the electrolyte layer and the porous layer is less than the above lower limit, there is a case where, due to a reduction in the length of an interface between the porous layer and the sealant, the electrolyte layer penetrates into a gap between the porous layer and the sealant and then reaches the first electrode layer so that the electrolyte layer comes into direct contact with the first electrode layer. On the other hand, if the difference in width between the electrolyte layer and the porous layer exceeds the above upper limit, there is a possibility that, due to a reduction in the area of the porous layer that contributes to power generation, significant improvement in power generation efficiency cannot be expected even when reverse electron transfer can be prevented.

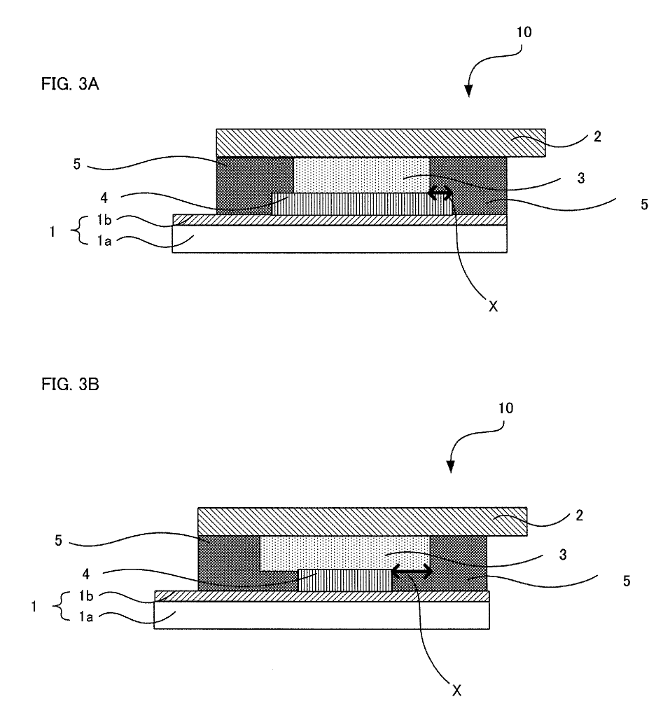

It is to be noted that the difference in width between the electrolyte layer and the porous layer refers to the distance from the edge of the electrolyte layer to the edge of the porous layer at any one of the ends of the dye-sensitized solar cell. FIGS. 3A and 3B are each a schematic view for explaining the difference in width between the electrolyte layer and the porous layer. As shown in FIGS. 3A and 3B, according to this embodiment, the difference in width between the electrolyte layer 3 and the porous layer 4 refers to the distance X from the edge of the electrolyte layer 3 to the edge of the porous layer 4.

2. Electrolyte Layer

Hereinbelow, the electrolyte layer used in this embodiment will be described. The electrolyte layer used in this embodiment is provided between the base material for dye-sensitized solar cell and the counter electrode base material in the dye-sensitized solar cell according to this embodiment. Further, the electrolyte layer used in this embodiment is characterized by having a width different from that of the porous layer.

The electrolyte layer used in this embodiment may be in any form of gel, solid, or liquid. Further, the electrolyte layer used in this embodiment may be either one containing a redox pair or one containing no redox pair. In a case where the electrolyte layer used in this embodiment contains a redox pair, the redox pair is not particularly limited as long as it is one generally used for electrolyte layers of dye-sensitized solar cells. However, a combination of iodine and iodide or a combination of bromine and bromide is preferred.

Examples of the combination of iodine and iodide used as a redox pair in this embodiment include combinations of I₂ and a metal iodide such as LiI, NaI, KI, or CaI₂.

Examples of the combination of bromine and bromide include combinations of Br₂ and a metal bromide such as LiBr, NaBr, KBr, or CaBr₂.

In a case where the electrolyte layer is in liquid form, it may be composed of a redox pair and a solvent such as acetonitrile, methoxyacetonitrile, or propylene carbonate. Alternatively, the electrolyte layer may be composed of a redox pair and an ionic liquid containing, as a cation, an imidazolium salt as a solvent.

In a case where the electrolyte layer is in gel form, it may be either a physical gel or a chemical gel. As used herein, the “physical gel” refers to one formed by physical interaction at around room temperature, and the “chemical gel” refers to one formed by chemical bonds generated by a cross-linking reaction or the like.

Examples of the electrolyte layer in solid form include those made of CuI, polypyrrole, or polythiophene.

3. Porous Layer

Hereinbelow, the porous layer used in this embodiment will be described. The porous layer used in this embodiment contains dye-sensitizer-supported fine particles of a metal oxide semiconductor, is laminated on the first electrode layer of the base material for dye-sensitized solar cell (which will be described later), and is provided so as to come into contact with the electrolyte layer.

(Fine Particles of Metal Oxide Semiconductor)

The fine particles of a metal oxide semiconductor (metal oxide semiconductor fine particles) used in this embodiment are not particularly limited as long as they are made of a metal oxide having semiconductor characteristics. Examples of the metal oxide constituting the metal oxide semiconductor fine particles used in this embodiment include TiO₂, ZnO, SnO₂, ITO, ZrO₂, MgO, Al₂O₃, CeO₂, Bi₂O₃, Mn₃O₄, Y₂O₃, WO₃, Ta₂O₅, Nb₂O₅, and La₂O₃. The metal oxide semiconductor fine particles made of such a metal oxide are suitable for forming a porous layer having porous properties, and are preferably used in this embodiment because improvement in energy conversion efficiency and cost reduction can be achieved.

The metal oxide semiconductor fine particles used in this embodiment may be made of the same metal oxide or two or more different metal oxides. Further, the metal oxide semiconductor fine particles used in this embodiment may have a core-shell structure in which a core fine particle made of one metal oxide semiconductor is coated with a shell made of another metal oxide semiconductor.

Among others, metal oxide semiconductor fine particles made of TiO₂ are most preferably used in this embodiment. This is because TiO₂ is particularly excellent in semiconductor characteristics.

The average particle size of the metal oxide semiconductor fine particles used in this embodiment is not particularly limited as long as the porous layer can have a specific surface area within a desired range, but is usually preferably in the range of 1 nm to 10 μm, and particularly preferably in the range of 10 nm to 1000 nm. If the average particle size is less than the above lower limit, there is a case where the individual metal oxide semiconductor fine particles agglomerate to form secondary particles. On the other hand, if the average particle size exceeds the above upper limit, there is a possibility that not only an increase in the thickness of the porous layer but also a reduction in the porosity, i.e., specific surface area, of the porous layer occurs. If the specific surface area of the porous layer is reduced, for example, there is a case where it is difficult for the porous layer to support a dye sensitizer in an amount sufficient to achieve photoelectric conversion.

It is to be noted that the average particle size of the metal oxide semiconductor fine particles refers to an average primary particle size.

The metal oxide semiconductor fine particles used in this embodiment may be metal oxide semiconductor fine particles having the same average particle size or two or more types of metal oxide semiconductor fine particles having different average particle sizes. The use of a combination of two or more types of metal oxide semiconductor fine particles having different average particle sizes has the advantage that light scattering effect in the porous layer can be enhanced and therefore the dye-sensitized solar cell according to this embodiment has higher power generation efficiency.

When two or more types of metal oxide semiconductor fine particles having different average particle sizes are used in this embodiment, an example of a combination of different average particle sizes is a combination of metal oxide semiconductor fine particles having an average particle size of 10 nm to 50 nm and metal oxide semiconductor fine particles having an average particle size of 50 nm to 800 nm.

(Dye Sensitizer)

The dye sensitizer used in this embodiment is not particularly limited as long as it can absorb light to generate electromotive force. Examples of such a dye sensitizer include organic pigments and metal complex pigments. Examples of the organic pigments include acridine-based pigments, azo-based pigments, indigo-based pigments, quinone-based pigments, coumarin-based pigments, merocyanine-based pigments, and phenylxanthene-based pigments. Among these organic pigments, coumarin-based pigments are preferably used in this embodiment. On the other hand, as the metal complex pigments, ruthenium-based pigments are preferably used. Among them, ruthenium bipyridine pigments and ruthenium terpyridine pigments, which are ruthenium complexes, are particularly preferably used. This is because such ruthenium complexes have wide light absorption wavelength ranges and therefore the wavelength range of light that can be converted into electricity can be significantly broadened.

(Optional Component)

The porous layer used in this embodiment may contain an optional component other than the metal oxide semiconductor fine particles. Examples of such an optional component used in this embodiment include binder resins. By allowing the porous layer to contain a binder resin, it is possible to improve the brittleness of the porous layer used in this embodiment.

The binder rein that can be used for the porous layer used in this embodiment is not particularly limited as long as the brittleness of the porous layer can be improved to a desired level. However, according to this embodiment, since the porous layer is provided so as to come into contact with the electrolyte layer, the binder resin used in this embodiment needs to have resistance to the electrolyte layer. Examples of such a binder resin include polyvinyl pyrrolidone, ethyl cellulose, and caprolactam.

It is to be noted that these binder resins that can be used in this embodiment may be used singly or in combination of two or more of them.

(Others)

The thickness of the porous layer used in this embodiment is not particularly limited, and can be appropriately determined depending on the intended use of the dye-sensitized solar cell according to this embodiment. However, the thickness of the porous layer used in this embodiment is usually preferably in the range of 1 μm to 100 μm, and particularly preferably in the range of 3 μm to 30 μm. If the thickness of the porous layer exceeds the above upper limit, there is a case where cohesion failure of the porous layer itself is likely to occur, which is likely to result in membrane resistance. On the other hand, if the thickness of the porous layer is less than the above lower limit, there is a possibility that it is difficult to form the porous layer so as to have a uniform thickness or the porous layer cannot sufficiently absorb sunlight due to a reduction in the amount of the dye sensitizer supported thereon and therefore performance failure occurs.

The porous layer used in this embodiment may have a structure composed of a single layer or a structure in which two or more layers are laminated. As such a structure of the porous layer in which two or more layers are laminated, any structure can be appropriately selected and used depending on, for example, a method for producing the base material for dye-sensitized solar cell used in this embodiment. For example, the porous layer may have a two-layer structure composed of an oxide semiconductor layer that comes into contact with the first electrode layer and an intermediate layer that is provided on the oxide semiconductor layer and has a porosity higher than that of the oxide semiconductor layer. This is because by allowing the porous layer to have such a two-layer structure composed of an oxide semiconductor layer and an intermediate layer, it is possible to easily form the porous layer used in this embodiment by a so-called transfer method. More specifically, the porous layer used in this embodiment can be formed by a method in which the porous layer and the first electrode layer are formed on a heat-resistant substrate by burning and are then transferred onto the base material. Therefore, by allowing the porous layer used in this embodiment to have the above-described two-layer structure composed of an oxide semiconductor layer and an intermediate layer, it is possible to reduce the adhesive force between the heat-resistant substrate and the porous layer without degrading the performance of the porous layer, which makes it easy to form the base material for dye-sensitized solar cell used in this embodiment by a transfer method.

In a case where the porous layer has a two-layer structure composed of the oxide semiconductor layer and the intermediate layer, the ratio of the thickness of the oxide semiconductor layer to the thickness of the intermediate layer is not particularly limited, but is preferably in the range of 10:0.1 to 10:5, and more preferably in the range of 10:0.1 to 10:3.

The porosity of the oxide semiconductor layer is preferably in the range of 10 to 60%, and particularly preferably in the range of 20 to 50%. If the porosity of the oxide semiconductor layer is less than the above lower limit, for example, there is a possibility that the porous layer cannot effectively absorb sunlight. On the other hand, if the porosity of the oxide semiconductor layer exceeds the above upper limit, there is a possibility that the porous layer cannot support a desired amount of dye sensitizer.

The porosity of the intermediate layer is not particularly limited as long as it is larger than the porosity of the oxide semiconductor layer, but is usually preferably in the range of 25 to 65%, and particularly preferably in the range of 30 to 60%.

It is to be noted that, in this embodiment, the porosity refers to the percentage of volume not occupied by the metal oxide semiconductor fine particles per unit volume. The porosity can be determined by measuring a pore volume by a gas absorption analyzer (Autosorb-1MP™ manufactured by Quantachrome Instruments) and then calculating the ratio of the pore volume to a volume per unit area. The porosity of the intermediate layer can be determined by measuring the porosity of the porous layer, in which the oxide semiconductor layer and the intermediate layer are laminated, and then performing calculation using a value obtained by measurement of only the oxide semiconductor layer.

4. Sealant

Hereinbelow, the sealant used in this embodiment will be described. The sealant used in this embodiment has the function of sealing the electrolyte layer and is provided so as to cover the ends of the electrolyte layer and the ends of the porous layer and to prevent the electrolyte layer from coming into contact with the first electrode layer, which makes it possible to prevent the occurrence of reverse electron transfer caused by direct contact between the electrolyte layer and the first electrode layer.

The sealant used in this embodiment is not particularly limited as long as it is composed of a material having durability against the electrolyte layer. Examples of such a sealant include: polyolefin-based resins such as various heat-sealable thermoplastic resins or thermoplastic elastomers, low-density polyethylene, high-density polyethylene, polypropylene, poly(1-butene), poly(4-methyl-1-pentene), and random or block copolymers of α-olefins such as ethylene, propylene, 1-butene, and 4-methyl-1-pentene; an ethylene-vinyl compound copolymer resin such as an ethylene-vinyl acetate copolymer, an ethylene-vinyl alcohol copolymer, and an ethylene-vinyl chloride copolymer; a styrene-based resin such as polystyrene, an acrylonitrile-styrene copolymer, ABS, and an α-methylstyrene-styrene copolymer; a vinyl-based resin such as polyvinyl alcohol, polyvinyl pyrrolidone, polyvinyl chloride, polyvinylidene chloride, vinyl chloride-vinylidene chloride copolymers, polyacrylic acid, polymethacrylic acid, polymethyl acrylate, and polymethyl methacrylate; a polyamide resin such as nylon 6, nylon 6-6, nylon 6-10, nylon 11, and nylon 12; a polyester resin such as polyethylene terephthalate, polybutylene terephthalate, and polyethylene naphthalate; polycarbonate; polyphenylene oxide; a cellulose derivative such as carboxy methyl cellulose and hydroxyl ethyl cellulose; starche such as oxidized starch, etherified starch, and dextrin; and a resin obtained by mixing two or more of them.

It is to be noted that the thickness of the sealant used in this embodiment is usually preferably in the range of 1 μm to 100 μm, and more preferably in the range of 1 μm to 50 μm. Here, the thickness of the sealant used in this embodiment corresponds to the distance between the base material for dye-sensitized solar cell and the counter electrode base material.

5. Base Material for Dye-Sensitized Solar Cell

Hereinbelow, the base material for dye-sensitized solar cell used in this embodiment will be described. The base material for dye-sensitized solar cell used in this embodiment comprises a base material and a first electrode layer provided on the base material.

Each of the components of such a base material for dye-sensitized solar cell will be described below.

(1) Base Material

First, the base material used in this embodiment will be described. The base material used in this embodiment is not particularly limited as long as it has self-supporting properties to be able to support the first electrode layer and the porous layer used in this embodiment. Therefore, the base material used in this embodiment may be a flexible material having flexibility or a rigid material having no flexibility such as quartz glass, Pyrex®, or a synthetic quartz plate. Among them, the base material used in this embodiment is preferably a flexible material, and particularly preferably a resin base material. This is because a resin base material is excellent in workability, which results in cost reduction.

Examples of such a resin base material include a base material made of a resin such as an ethylene/tetrafluoroethylene copolymer film, a biaxially-drawn polyethylene terephthalate film, a polyether sulfone (PES) film, a polyether ether ketone (PEEK) film, a polyether imide (PEI) film, a polyimide (PI) film, a polyester naphthalate (PEN) film, and a polycarbonate (PC) film. Among them, a biaxially-drawn polyethylene terephthalate (PET) film, a polyester naphthalate (PEN) film, and a polycarbonate (PC) film are preferably used in this embodiment.

The thickness of the base material used in this embodiment can be appropriately selected depending on factors such as the intended use of the dye-sensitized solar cell according to this embodiment, but is usually preferably in the range of 50 μm to 2000 μm, particularly preferably in the range of 75 μm to 1800 μm, and more preferably in the range of 100 μm to 1500 μm.

The base material used in this embodiment preferably has excellent heat resistance, weather resistance, and gas barrier properties against water vapor and other gases. By allowing the base material to have gas barrier properties, it is possible to improve, for example, temporal stability of the dye-sensitized solar cell according to this embodiment. Particularly, the base material used in this embodiment preferably has gas barrier properties such that oxygen permeability is 1 cc/m²/day·atm or less under conditions of a temperature of 23° C. and a humidity of 90% and water vapor permeability is 1 g/m²/day or less under conditions of a temperature of 37.8° C. and a humidity of 100%. According to this embodiment, any gas barrier layer may be provided on the base material to achieve such gas barrier properties.

(2) First Electrode Layer

The first electrode layer used in this embodiment will be described below. The first electrode layer used in this embodiment is provided on the base material described above.

The material of the first electrode layer used in this embodiment is not particularly limited as long as it has desired conductivity, and a conductive polymer material, a metal oxide, or the like can be used.

The metal oxide is not particularly limited as long as it has desired conductivity, but the metal oxide used in this embodiment preferably has sunlight permeability. Examples of such a metal oxide having sunlight permeability include SnO₂, ITO, IZO, and ZnO. Any of these metal oxides can be preferably used in this embodiment, but fluorine-doped SnO₂ (hereinafter, referred to as “FTO”) or ITO is particularly preferably used. This is because FTO and ITO are excellent in both conductivity and sunlight permeability.

On the other hand, examples of the conductive polymer material include polythiophene, polystyrenesulfonic acid (PSS), polyaniline (PA), polypyrrole, and polyethylene dioxythiophene (PEDOT). These conductive polymer materials may be used in combination of two or more of them.

The first electrode layer used in this embodiment may have a structure composed of a single layer or a structure in which two or more layers are laminated. Examples of such a structure in which two or more layers are laminated include one in which two or more layers made of materials different in work function from each other are laminated and one in which two or more layers made of metal oxides different from each other are laminated.

The thickness of the first electrode layer used in this embodiment is not particularly limited as long as it can realize desired conductivity that depends on factors such as the intended use of the dye-sensitized solar cell according to this embodiment. However, the thickness of the first electrode layer used in this embodiment is usually preferably in the range of 5 nm to 2000 nm, and particularly preferably in the range of 10 nm to 1000 nm. If the thickness of the first electrode layer exceeds the above upper limit, there is a case where it is difficult to make the first electrode layer uniform or it is difficult to achieve high photoelectric conversion efficiency due to a reduction in total light transmittance. On the other hand, if the thickness of the first electrode layer is less than the above lower limit, there is a possibility that the first electrode layer is poor in conductivity.

It is to be noted that, when the first electrode layer is composed of two or more layers, the thickness refers to the total thickness of all the layers.

(3) Optional Component

The base material for dye-sensitized solar cell used in this embodiment comprises at least the base material and the first electrode layer, but if necessary, may comprise another optional component. An example of such an optional component used in this embodiment is an auxiliary electrode made of a conductive material and provided so as to come into contact with the first electrode layer. By providing such an auxiliary electrode, it is possible, when the first electrode layer is poor in conductivity, to compensate for the lack of conductivity. This is advantageous in that the dye-sensitized solar cell according to the present invention can have higher power generation efficiency.

(4) Method for Producing Base Material for Dye-Sensitized Solar Cell

A method for producing the above-described base material for dye-sensitized solar cell is not particularly limited as long as a base material for dye-sensitized solar cell having such a structure as described above can be produced, and any generally-known method may be appropriately used for reference purposes.

6. Counter Electrode Base Material

Hereinbelow, the counter electrode base material used in this embodiment will be described. The counter electrode base material used in this embodiment functions as an electrode.

The counter electrode base material used in this embodiment is not particularly limited as long as it functions as an electrode, and examples of such a counter electrode base material include one composed of a metal foil and one having a structure in which a second electrode layer is provided on a counter base material.

When the counter electrode base material used in this embodiment is composed of a metal foil, the metal foil itself functions as an electrode, and therefore the counter electrode base material does not always need to have another component. Examples of the metal foil used as the counter electrode base material include those made of titanium, stainless steel, or aluminum, copper. Further, when the counter electrode base material used in this embodiment is composed of a metal foil, the thickness of the metal foil is not particularly limited as long as desired self-supporting properties can be imparted to the counter electrode base material, but is usually preferably in the range of 5 μm to 1000 μm, more preferably in the range of 10 μm to 500 μm, and even more preferably in the range of 20 μm to 200 μm.

On the other hand, when the counter electrode base material used in this embodiment has a structure in which a second electrode layer is provided on a counter base material, the second electrode layer is not particularly limited as long as it is made of a conductive material having desired conductivity, and one made of a conductive polymer material, a metal oxide, or the like can be used. Examples of the conductive polymer material and the metal oxide to be used include those mentioned above as materials used for the first electrode layer.

The second electrode layer used in this embodiment may have a structure composed of a single layer or a structure in which two or more layers are laminated. Examples of such a structure in which two or more layers are laminated include one in which two or more layers made of materials different in work function from each other are laminated and one in which two or more layers made of metal oxides different from each other are laminated. The thickness of the second electrode layer used in this embodiment is usually preferably in the range of 5 nm to 2000 nm, and particularly preferably in the range of 10 nm to 1000 nm.

The counter base material used in this embodiment is the same as the base material used for the base material for dye-sensitized solar cell, and therefore a description thereof is omitted here.

If necessary, the counter electrode base material used in this embodiment may further include a catalyst layer.

By providing a catalyst layer in the counter electrode base material, it is possible to further enhance the power generation efficiency of the dye-sensitized solar cell according to this embodiment. Examples of such a catalyst layer include, but are not limited to, one formed on the second electrode layer by vapor deposition of Pt and one made of polyethylene dioxythiophene (PEDOT), polystyrenesulfonic acid (PSS), polyaniline (PA), para-toluenesulfonic acid (PTS), or a mixture of two or more of them. It is to be noted that when the counter electrode base material used in this embodiment has the counter base material and the second electrode layer, the catalyst layer is formed on the second electrode layer.

7. Examples of Dye-Sensitized Solar Cell

The dye-sensitized solar cell according to this embodiment may have a structure in which a plurality of cells provided between a pair of the base material for dye-sensitized solar cell and the counter electrode base material by patterning of the porous layer and the counter electrode base material are connected together. By allowing the dye-sensitized solar cell according to this embodiment to have such a structure, it is possible to increase the electromotive force of the dye-sensitized solar cell according to this embodiment.

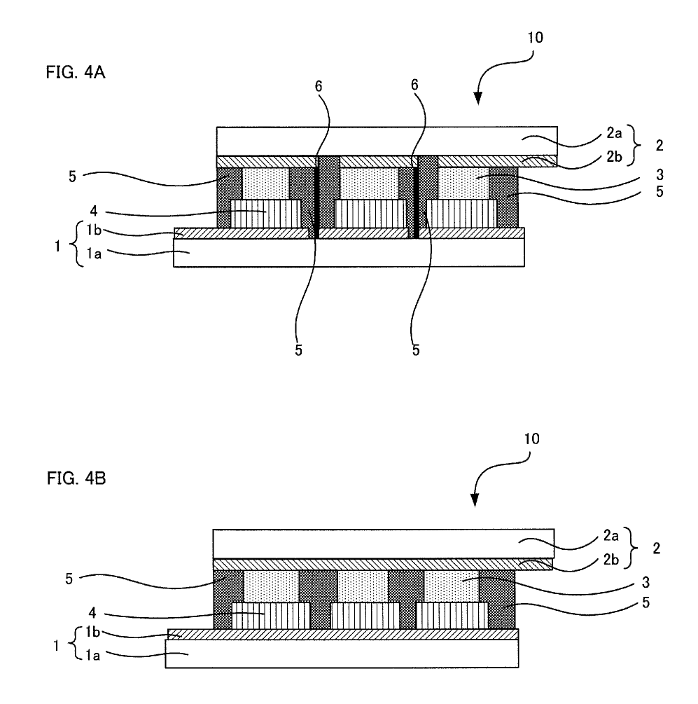

FIGS. 4A and 4B are each a schematic sectional view of one example of the dye-sensitized solar cell according to this embodiment having a structure in which a plurality of cells provided between a pair of the base material for dye-sensitized solar cell and the counter electrode base material, the counter electrode base material being one composed of the counter base material and the second electrode layer, are connected together. More specifically, FIGS. 4A and 4B are each a schematic sectional view of one example of the dye-sensitized solar cell according to this embodiment in which three cells are connected together; in series in FIG. 4A and in parallel in FIG. 4B. The reference sign 6 denotes wiring.

The shape of the pattern of the porous layer etc. can be arbitrarily determined depending on factors such as the desired electromotive force of the dye-sensitized solar cell according to this embodiment. However, according to this embodiment, the pattern most preferably has a striped shape.

8. Method for Producing Dye-Sensitized Solar Cell

Hereinbelow, a method for producing the dye-sensitized solar cell according to this embodiment will be described. The dye-sensitized solar cell according to this embodiment can be produced by, for example, forming the porous layer on the base material for dye-sensitized solar cell and then forming the electrolyte layer between the base material for dye-sensitized solar cell and the counter electrode base material.

According to this embodiment, a method for forming the electrolyte layer between the base material for dye-sensitized solar cell and the counter electrode base material is not particularly limited as long as the electrolyte layer can be formed with high thickness accuracy. An example of such a method is one in which the sealant is provided so as to cover the periphery of the porous layer formed on the base material for dye-sensitized solar cell and to cover the surface of the first electrode layer, and then the electrolyte layer is formed on the porous layer so as to be located inside and surrounded by the sealant, and then the counter electrode base material is provided on the electrolyte layer.

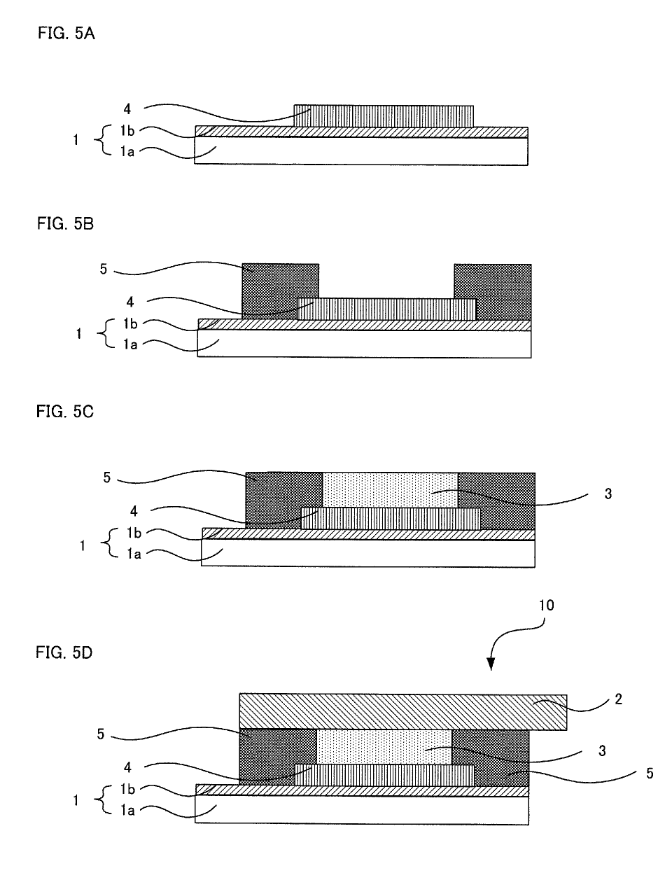

Such a method for producing the dye-sensitized solar cell according to this embodiment will be described with reference to the drawings. FIGS. 5A to 5D are schematic views for explaining one example of the method for producing the dye-sensitized solar cell according to this embodiment. As shown in FIGS. 5A to 5D, the dye-sensitized solar cell 10 according to this embodiment can be produced by a method in which the base material for dye-sensitized solar cell 1 having the porous layer 4 laminated thereon is prepared (FIG. 5A), the sealant 5 is provided on the surface of the first electrode layer 1b so as to surround the porous layer 4 (FIG. 5B), the electrolyte layer 3 is formed on the porous layer 4 so as to be located inside and surrounded by the sealant 5 (FIG. 5C), and the counter electrode base material 2 is provided on the electrolyte layer 3 (FIG. 59).

B. Second Embodiment of Dye-Sensitized Solar Cell

1. Dye-Sensitized Solar Cell

A dye-sensitized solar cell according to a second embodiment of the present invention comprises: a base material for dye-sensitized solar cell having a base material and a first electrode layer provided on the base material; a counter electrode base material arranged so as to oppose to the base material for dye-sensitized solar cell and functions as an electrode; an electrolyte layer provided between the base material for dye-sensitized solar cell and the counter electrode base material; a porous layer laminated on the counter electrode base material, provided so as to come into contact with the electrolyte layer, and contains a dye-sensitizer-supported fine particle of a metal oxide semiconductor; and a sealant provided so as to seal the electrolyte layer. The dye-sensitized solar cell according to this embodiment is characterized in that the electrolyte layer and the porous layer have different widths and the sealant is provided so as to cover the ends of the electrolyte layer and the ends of the porous layer and to prevent the electrolyte layer from coming into contact with the surface of the counter electrode base material.

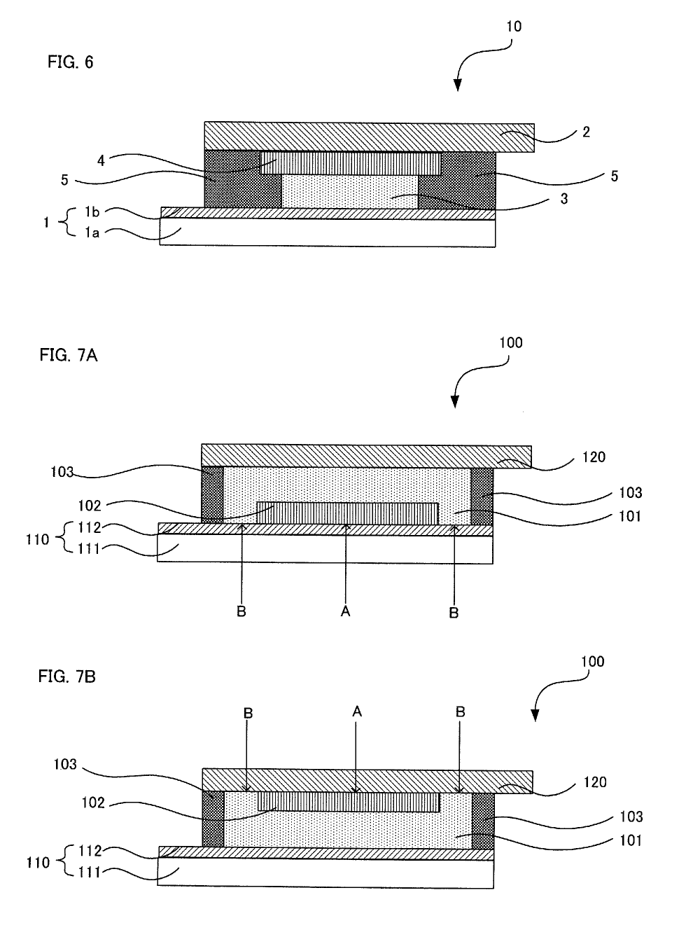

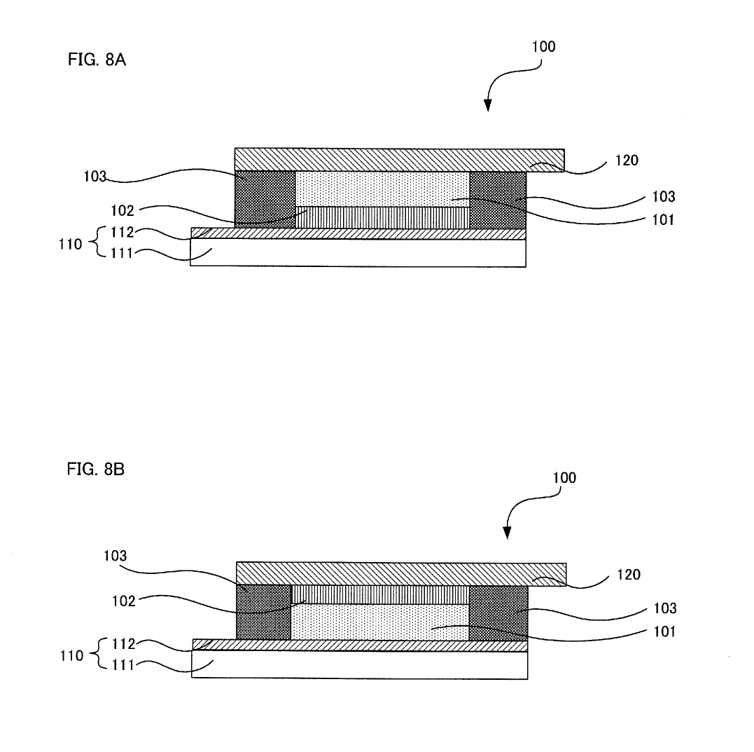

Such a dye-sensitized solar cell according to this embodiment will be described with reference to the drawings. FIG. 6 is a schematic sectional view of one example of the dye-sensitized solar cell according to this embodiment. As shown in FIG. 6, the dye-sensitized solar cell 10 according to this embodiment comprises: the base material for dye-sensitized solar cell 1 having the base material 1a and the first electrode layer 1b provided on the base material 1a; the counter electrode base material 2 arranged so as to oppose to the base material for dye-sensitized solar cell 1 and functions as an electrode; the electrolyte layer 3 provided between the base material for dye-sensitized solar cell 1 and the counter electrode base material 2; the porous layer 4 laminated on the counter electrode base material 2, provided so as to come into contact with the electrolyte layer 3, and contains dye-sensitizer-supported fine particles of a metal oxide semiconductor; and the sealant 5 provided so as to seal the electrolyte layer 3.

The dye-sensitized solar cell 10 as one example of this embodiment is characterized in that the electrolyte layer 3 and the porous layer 4 have different widths and the sealant 5 is provided so as to cover the ends of the electrolyte layer 3 and the ends of the porous layer 4 and to prevent the electrolyte layer 3 from coming into contact with the surface of the counter electrode base material 2.

According to this embodiment, the sealant is provided so as to cover the ends of the electrolyte layer and the ends of the porous layer and to prevent the electrolyte layer from coming into contact with the counter electrode base material, which makes it possible to eliminate an area where the electrolyte layer comes into direct contact with the counter electrode base material (i.e., an interface indicated by an arrow B in FIG. 7B) from the dye-sensitized solar cell according to this embodiment.

Further, the electrolyte layer and the porous layer have different widths, and therefore the length of an interface between the porous layer and the sealant can be increased. This makes it possible to prevent the electrolyte layer from reaching the counter electrode base material even when the electrolyte layer penetrates into a gap between the porous layer and the sealant. Therefore, according to the present invention, it is possible to prevent reverse electron transfer caused by direct contact between the electrolyte layer and the counter electrode base material.

For this reason, according to the present invention, it is possible to obtain a dye-sensitized solar cell that prevents reverse electron transfer by a simple method and has significantly-improved power generation efficiency.

Here, examples of the dye-sensitized solar cell according to this embodiment in which the porous layer and the electrolyte layer have different widths are the same as those described above in the paragraph “A. First Embodiment of Dye-Sensitized Solar Cell”.

2. Electrolyte Layer

The electrolyte layer used in this embodiment is the same as that described above in the paragraph “A. First Embodiment of Dye-Sensitized Solar Cell”, and therefore a description thereof is omitted here.

3. Porous Layer

Hereinbelow, the porous layer used in this embodiment will be described. The porous layer used in this embodiment contains dye-sensitizer-supported fine particles of a metal oxide semiconductor, is laminated on the counter electrode base material, and is provided so as to come into contact with the electrolyte layer. It is to be noted that the porous layer used in this embodiment is the same as that described above in the paragraph “A. First Embodiment of Dye-Sensitized Solar Cell” except that it is laminated not on the first electrode layer but on the counter electrode base material.

4. Sealant

Hereinbelow, the sealant used in this embodiment will be described. The sealant used in this embodiment has the function of sealing the electrolyte layer, and is provided so as to cover the ends of the electrolyte layer and the ends of the porous layer and to prevent the electrolyte layer from coming into contact with the counter electrode base material to prevent the occurrence of reverse electron transfer caused by direct contact between the electrolyte layer and the counter electrode base material.

It is to be noted that the sealant used in this embodiment is the same as that described above in the paragraph “A. First Embodiment of Dye-Sensitized Solar Cell” except that it is provided to prevent the electrolyte layer from coming into contact not with the first electrode layer but with the counter electrode base material.

5. Base Material for Dye-Sensitized Solar Cell

The base material for dye-sensitized solar cell used in this embodiment is the same as that described above in the paragraph “A. First Embodiment of Dye-Sensitized Solar Cell”.

It is to be noted that the base material for dye-sensitized solar cell used in this embodiment preferably has a catalyst layer provided on the first electrode layer thereof. By providing a catalyst layer on the first electrode layer, it is possible to further enhance the power generation efficiency of the dye-sensitized solar cell according to this embodiment. Examples of such a catalyst layer include, but are not limited to, one formed on the first electrode layer by vapor-deposition of Pt and one made of polyethylene dioxythiophene (PEDOT), polystyrenesulfonic acid (PSS), polyaniline (PA), para-toluenesulfonic acid (PTS), or a mixture of two or more of them. When provided on the first electrode layer, the catalyst layer needs to show its catalytic ability without impairing light permeability. For example, when the catalyst layer is one formed by vapor-deposition of Pt, the thickness of Pt is preferably 0.1 to 20 nm. If the thickness of Pt is less than 0.1 nm, there is a possibility that the catalyst layer is poor in catalytic ability. On the other hand, if the thickness of Pt exceeds 20 nm, there is a possibility that the amount of transmitted light is short.

6. Counter Electrode Base Material

The counter electrode base material used in this embodiment is the same as that described above in the paragraph “A. First Embodiment of Dye-Sensitized Solar Cell”.

7. Examples of Dye-Sensitized Solar Cell

The dye-sensitized solar cell according to this embodiment may have a structure in which a plurality of cells provided between a pair of the base material for dye-sensitized solar cell and the counter electrode base material by pattering of the porous layer etc. and the first electrode layer etc. of the base material for dye-sensitized solar cell are connected together. By allowing the dye-sensitized solar cell according to this embodiment to have such a structure, it is possible to increase the electromotive force of the dye-sensitized solar cell according to this embodiment.

8. Method for Producing Dye-Sensitized Solar Cell

Hereinbelow, a method for producing the dye-sensitized solar cell according to this embodiment will be described. The dye-sensitized solar cell according to this embodiment can be produced by, for example, forming the porous layer on the counter electrode base material and then forming the electrolyte layer between the base material for dye-sensitized solar cell and the counter electrode base material. Such a production method is the same as that described above in the paragraph “A. First Embodiment of Dye-Sensitized Solar Cell” except that the porous layer is formed on the counter electrode base material, and therefore a description thereof is omitted here.

It is to be noted that the present invention is not limited to the above-described embodiments. The above-described embodiments are merely illustrative, and those that have substantially the same structure as the technical idea described in the claims of the present invention and demonstrate the same functions and effects are included in the technical scope of the present invention.

### EXAMPLES

Hereinbelow, the present invention will be more specifically described with reference to the following examples.

### Example 1

A 1 mm-thick glass substrate was used as a base material, and a first electrode layer made of FTO was formed on the base material by sputtering so as to have a thickness of 400 nm. Then, the base material having the first electrode layer was cut into a 20 mm×20 mm square to obtain a base material for dye-sensitized solar cell. The surface resistivity of the first electrode layer was 10Ω/□.

Then, an ink obtained by adding 4 wt % of ethyl cellulose and ethanol to titanium oxide powder (manufactured by Nippon Aerosil Co., Ltd. under the trade name of “P-25”) was applied onto the first electrode layer in an area of a 10 mm×10 mm square so as to have a dried film thickness of 8 μm, and was burned at 500° C. for 15 minutes to obtain a porous layer.

Then, a dye solution was prepared by dissolving Ruthenium 535-bisTBA (trade name, manufactured by SOLARONIX SA) as a dye sensitizer in an ethanol solvent to achieve a concentration of 5×10⁻⁴ M. Then, the porous layer was immersed in the dye solution for 12 hours to adsorb the dye to the porous layer, and was then washed with ethanol and dried.

Then, an alicyclic epoxy resin (0.5 g, manufactured by Daicel Corporation under the trade name of “2021”) and a silicone resin (0.5 g, manufactured by Toray Silicone Co., Ltd. under the trade name of “SH6018”) were added to and dissolved in a mixed solution of 1-methyl-3-propylimidazolium iodide (8 g) and propionitrile (2 g), and iodine was dissolved therein so that an iodine concentration was 0.03 M to prepare an electrolyte layer composition.

Then, a sealant (HIMILAN™ 25 μm manufactured by Du Pont-Mitsui Polychemicals Co., Ltd.) was provided on the first electrode layer so that the periphery of the porous layer was covered with the 2 mm-thick sealant, and then the electrolyte layer composition was laminated on the porous layer surrounded by the sealant to obtain an electrolyte layer.

Then, a counter electrode base material composed of a glass substrate as a counter base material and a second electrode layer formed by laminating 15 nm-thick platinum on a fluorine-doped tin oxide electrode by sputtering was placed so that the second electrode layer came into contact with the electrolyte layer, and was heated at 170° C. for 1 minute to produce a dye-sensitized solar cell according to the present invention.

### Example 2

A dye-sensitized solar cell was produced in the same manner as in Example 1 except that 5 wt % of ethyl cellulose was added to the electrolyte layer composition prepared in Example 1.

### Example 3

A 100 μm-thick PEN substrate was used as a base material, and a first electrode layer made of ITO was formed on the base material by ion plating so as to have a thickness of 200 nm. Then, the base material having the first electrode layer was cut into a 20 mm×20 mm square. The surface resistivity of the first electrode layer was 15Ω/□.

Then, a titanium oxide paste (Ti-Nanoxide T-L™ manufactured by Solaronix SA) was applied onto the first electrode layer in an area of a 10 mm×10 mm square so as to have a dried film thickness of 8 μm, and was then dried at 150° C. for 1 hour to obtain a porous layer.

Then, a dye was adsorbed to the porous layer in the same manner as in Example 1, and was then washed with ethanol and dried.

Then, a sealant (HIMILAN™ 25 μm manufactured by Du Pont-Mitsui Polychemicals Co., Ltd.) was provided on the first electrode layer so that the periphery of the porous layer was covered with the 2 mm-thick sealant, and then an electrolyte layer composition was laminated on the porous layer surrounded by the sealant in the same manner as in Example 1 to obtain an electrolyte layer.

Then, a counter electrode base material composed of a glass substrate as a counter base material and a second electrode layer formed by depositing platinum on a fluorine-doped tin oxide electrode was placed so that the second electrode layer came into contact with the electrolyte layer, and was heated at 140° C. for 3 minutes to produce a dye-sensitized solar cell according to the present invention.

### Example 4

A dye-sensitized solar cell was produced in the same manner as in Example 1 except that a 80 μm-thick titanium foil on which 15 nm-thick platinum had been laminated by sputtering was used as a counter electrode base material and placed so that the platinum came into contact with the electrolyte layer, and that the thickness of the sealant (HIMILAN™ 25 μm manufactured by Du Pont-Mitsui Polychemicals Co., Ltd.) provided on the first electrode layer so as to cover the periphery of the porous layer was changed to 1 mm.

### Example 5

A 1 mm-thick glass substrate was used as a base material, and a first electrode layer made of ITO was formed on the base material by sputtering so as to have a thickness of 200 nm. Then, 1 nm-thick platinum was laminated on the first electrode layer by sputtering.

Then, the base material having the first electrode layer was cut into a 20 mm×20 mm square to obtain a base material for dye-sensitized solar cell. The surface resistivity of the first electrode layer was 9Ω/□.

Then, an ink prepared by adding 4 wt % of ethyl cellulose and ethanol to titanium oxide powder (manufactured by Nippon Aerosil Co., Ltd. under the trade name of “P-25”) was applied onto an 80 μm-thick titanium foil as a counter electrode base material in an area of a 10 mm×10 mm square so as to have a dried film thickness of 7 μm, and was then burned at 500° C. for 15 minutes to obtain a porous layer.

Then, a dye was adsorbed to the porous layer in the same manner as in Example 1, and was then washed with ethanol and dried.

Then, 5 wt % of ethyl cellulose was added to the electrolyte layer composition prepared in Example 1 to prepare an electrolyte layer composition.

Then, a sealant (HIMILAN™ 25 μm manufactured by Du Pont-Mitsui Polychemicals Co., Ltd.) was provided on the counter electrode base material so that the periphery of the porous layer was covered with the 1 mm-thick sealant, and the electrolyte layer composition was laminated on the porous layer surrounded by the sealant to obtain an electrolyte layer.

Then, the base material for dye-sensitized solar cell was placed so that the platinum came into contact with the electrolyte layer, and was then heated at 170° C. for 1 minute to produce a dye-sensitized solar cell according to the present invention.

### Example 6

A 100 μm-thick PEN film was used as a base material, and a first electrode layer made of ITO was formed on the base material by ion plating so as to have a thickness of 200 nm. Then, 1 nm-thick platinum was laminated on the first electrode layer by sputtering. Then, the base material having the first electrode layer was cut into a 20 mm×20 mm square to obtain a base material for dye-sensitized solar cell. The surface resistivity of the first electrode layer was 15Ω/□. A dye-sensitized solar cell according to the present invention was produced in the same manner as in Example 5 except that the base material for dye-sensitized solar cell was placed so that the platinum came into contact with the electrolyte layer, and was then heated at 140° C. for 3 minutes.

### Example 7

A dye-sensitized solar cell was produced in the same manner as in Example 5 except that the thickness of platinum laminated by sputtering was changed to 5 nm.

### Example 8

A dye-sensitized solar cell was produced in the same manner as in Example 5 except that the thickness of platinum deposited by sputtering was changed to 10 nm.

### Comparative Example 1

A dye-sensitized solar cell was produced in the same manner as in Example 1 except that the size of the porous layer was changed to 8 mm×8 mm and a 1 mm-gap was provided between the sealant and the porous layer.

### Comparative Example 2

A dye-sensitized solar cell was produced in the same manner as in Example 3 except that the size of the porous layer was changed to 8 mm×8 mm and a 1 mm-gap was provided between the sealant and the porous layer.

### Comparative Example 3

A dye-sensitized solar cell was produced in the same manner as in Example 8 except that the thickness of platinum laminated by sputtering was changed to 10 nm, the size of the porous layer was changed to 8 mm×8 mm, and a 1 mm-gap was provided between the sealant and the porous layer.

The evaluation results of the dye-sensitized solar cells produced in Examples 1 to 8 and Comparative Examples 1 to 3 are shown in Table 1. The evaluation of these dye-sensitized solar cells was performed just after their production and after storage in an atmosphere having a temperature of 65° C. and a relative humidity of 60% for 168 hours. It is to be noted that the performance of each of the dye-sensitized solar cells was evaluated by determining its current-voltage characteristics with the use of artificial sunlight (AM 1.5, irradiation intensity: 100 mW/cm²) as a light source and a source measure unit (Keithley 2400 series).

TABLE 1

| | | Open circuit | Short circuit | Fill | Conversion |
|---|---|---|---|---|---|
| | | voltage [V] | current [mA/cm²] | factor | efficiency [%] |
| Example 1 | Just after production | 0.73 | 10.2 | 0.64 | 4.8 |
| | After storage (65° C. × 60% × 168 h) | 0.72 | 10.1 | 0.64 | 4.7 |
| Example 2 | Just after production | 0.72 | 9.8 | 0.61 | 4.3 |
| | After storage (65° C. × 60% × 168 h) | 0.72 | 9.7 | 0.61 | 4.3 |
| Example 3 | Just after production | 0.72 | 9.5 | 0.61 | 4.2 |
| | After storage (65° C. × 60% × 168 h) | 0.71 | 9.4 | 0.61 | 4.1 |
| Example 4 | Just after production | 0.73 | 11.1 | 0.65 | 5.3 |
| | After storage (65° C. × 60% × 168 h) | 0.72 | 11.0 | 0.65 | 5.1 |
| Example 5 | Just after production | 0.73 | 11.1 | 0.66 | 5.3 |
| | After storage (65° C. × 60% × 168 h) | 0.73 | 11.0 | 0.66 | 5.3 |
| Example 6 | Just after production | 0.72 | 9.9 | 0.64 | 4.6 |
| | After storage (65° C. × 60% × 168 h) | 0.72 | 9.7 | 0.64 | 4.5 |
| Example 7 | Just after production | 0.73 | 8.1 | 0.67 | 4.0 |
| | After storage (65° C. × 60% × 168 h) | 0.73 | 8.2 | 0.67 | 4.0 |
| Example 8 | Just after production | 0.72 | 7.4 | 0.66 | 3.5 |
| | After storage (65° C. × 60% × 168 h) | 0.72 | 7.3 | 0.66 | 3.5 |
| Comparative | Just after production | 0.59 | 8.3 | 0.58 | 2.8 |
| Example 1 | After storage (65° C. × 60% × 168 h) | 0.56 | 7.6 | 0.57 | 2.4 |
| Comparative | Just after production | 0.60 | 8.2 | 0.57 | 2.9 |
| Example 2 | After storage (65° C. × 60% × 168 h) | 0.56 | 7.6 | 0.57 | 2.4 |
| Comparative | Just after production | 0.56 | 6.5 | 0.63 | 2.3 |
| Example 3 | After storage (65° C. × 60% × 168 h) | 0.52 | 6.3 | 0.62 | 2.0 |

### REFERENCE SIGNS LIST

1 Base material for dye-sensitized solar cell
1a Base material
1b First electrode layer
2 Counter electrode base material
2a Counter base material
2b Second electrode layer
3 Electrolyte layer
4 Porous layer
5 Sealant
6 Wiring
10 Dye-sensitized solar cell

1.-4. (canceled)

5. A dye-sensitized solar cell comprising:
a base material for dye-sensitized solar cell having a base material and a first electrode layer provided on the base material;
a counter electrode base material arranged so as to oppose to the base material for dye-sensitized solar cell and functions as an electrode;
an electrolyte layer provided between the base material for dye-sensitized solar cell and the counter electrode base material;
a porous layer laminated on the first electrode layer of the base material for dye-sensitized solar cell, provided so as to come into contact with the electrolyte layer, and contains a dye-sensitizer-supported fine particle of a metal oxide semiconductor; and
a sealant provided so as to seal the electrolyte layer, wherein the electrolyte layer and the porous layer have different widths, and the sealant is provided so as to cover ends of the electrolyte layer and ends of the porous layer and to prevent the electrolyte layer from coming into contact with the first electrode layer.

6. A dye-sensitized solar cell comprising:
a base material for dye-sensitized solar cell having a base material and a first electrode layer provided on the base material;
a counter electrode base material arranged so as to oppose to the base material for dye-sensitized solar cell and functions as an electrode;
an electrolyte layer provided between the base material for dye-sensitized solar cell and the counter electrode base material;
a porous layer laminated on the counter electrode base material, provided so as to come into contact with the electrolyte layer, and contains a dye-sensitizer-supported fine particle of a metal oxide semiconductor; and
a sealant provided so as to seal the electrolyte layer, wherein the electrolyte layer and the porous layer have different widths, and the sealant is provided so as to cover ends of the electrolyte layer and ends of the porous layer and to prevent the electrolyte layer from coming into contact with a surface of the counter electrode base material.

7. The dye-sensitized solar cell according to claim 5, wherein the electrolyte layer has a width smaller than a width of the porous layer.

8. The dye-sensitized solar cell according to claim 5, wherein a difference in width between the electrolyte layer and the porous layer is 0.5 mm to 5 mm.

9. The dye-sensitized solar cell according to claim 6, wherein the electrolyte layer has a width smaller than a width of the porous layer.

10. The dye-sensitized solar cell according to claim 6, wherein a difference in width between the electrolyte layer and the porous layer is 0.5 mm to 5 mm.
